(19) United States
(12) Patent Application Publication
(10) Pub. No.: US 2026/0155175 A1
(43) Pub. Date: Jun. 4, 2026

(54) MEMORY APPARATUS, MEMORY SYSTEM, AND OPERATION METHOD OF MEMORY SYSTEM

(71) Applicant: SK Hynix Inc., Icheon-si (KR)

(72) Inventors: Beom Seok LEE, Icheon-si (KR); Myoungsub KIM, Icheon-si (KR); Ung Hee PARK, Icheon-si (KR); Jae Hyuk PARK, Icheon-si (KR); Sang Chul OH, Icheon-si (KR); Won Jun LEE, Icheon-si (KR)

(21) Appl. No.: 19/234,703

(22) Filed: Jun. 11, 2025

(30) Foreign Application Priority Data
Nov. 29, 2024 (KR) 10-2024-0175668

(51) Int. Cl. G11C 13/00; G06F 11/10

(52) U.S. Cl. CPC G11C 13/0033; G06F 11/1044

(57) ABSTRACT

A memory system includes: a memory apparatus including a plurality of memory cells; and a controller that controls a curing operation to be performed on a first memory cell among the plurality of memory cells when the number of access operations performed on the first memory cell exceeds a preset number of times.

### CROSS-REFERENCE TO RELATED APPLICATION

This application claims priority under 35 U.S.C. § 119(a) to Korean Patent Application No. 10-2024-0175668 filed on Nov. 29, 2024, which is incorporated herein by reference in its entirety.

### BACKGROUND

### 1. Technical Field

Embodiments of the present disclosure relate to an integrated circuit technology, and, to a memory apparatus, a memory system, and an operation method of a memory system.

### 2. Related Art

Recently, with the miniaturization, low power consumption, high performance, and diversification of electronic devices, memories capable of storing information in various electronic appliances such as computers and portable communication devices are desirable. In addition, research on memories having various characteristics is also ongoing.

Memories under research include memories that can store data by using the characteristic of switching between different resistance states depending on a voltage or a current applied. Such memories include a resistive random access memory (RRAM), a phase-change random access memory (PRAM), a ferroelectric random access memory (FRAM), a magnetic random access memory (MRAM), an e-fuse, and the like.

### SUMMARY

In an embodiment, a memory system may include: a memory apparatus including a plurality of memory cells; and a controller that controls a curing operation to be performed on a first memory cell among the plurality of memory cells when the number of access operations performed on the first memory cell exceeds a preset number of times.

In another embodiment, a memory system may include: a memory apparatus including a plurality of memory cells; and a controller that controls a curing operation to be performed on a first memory cell among the plurality of memory cells when an error rate of the first memory cell exceeds a preset value.

In an embodiment, an operation method of a memory system may include: managing numbers of access operations for a plurality of memory cells; determining whether a first memory cell exists among the plurality of memory cells, the number of access operations performed on the first memory cell exceeding a set number of times; determining data stored in the first memory cell when the first memory cell exists; and performing a curing operation on the first memory cell according to a result of the determining.

In another embodiment, an operation method of a memory system may include: correcting and managing an error in data output from a plurality of memory cells; determining states of the plurality of memory cells each according to an error rate calculated in the managing; and performing a curing operation based on the error rate.

In an embodiment, a memory apparatus may include: a cell array including a plurality of memory cells; a write circuit that stores data in at least first memory cell of the plurality of memory cells on the basis of a write command; and a read circuit that outputs data from at least second memory cell of the plurality of memory cells on the basis of a read command, wherein the write circuit cures at least third memory cell of the plurality of memory cells on the basis of a curing command.

### BRIEF DESCRIPTION OF THE DRAWINGS

FIG. 1 is a diagram for explaining the configuration of a memory system in accordance with an embodiment of the present disclosure.

FIGS. 2 and 3 each are diagrams for explaining a write operation of a memory apparatus in accordance with an embodiment of the present disclosure.

FIG. 4 is a diagram for explaining a read operation of the memory apparatus in accordance with an embodiment of the present disclosure.

FIGS. 5A, 5B, 5C, and 6 each are diagrams for explaining the characteristics of a memory cell in accordance with an embodiment of the present disclosure.

FIGS. 7A, 7B, and 7C each are a diagram for explaining a curing pulse in accordance with the embodiment of the present disclosure.

FIGS. 8A, 8B, 8C, 9A, 9B, and 9C each are diagrams for explaining a curing operation in accordance with an embodiment of the present disclosure.

FIG. 10 is a diagram for explaining an operation method of the memory system in accordance with an embodiment of the present disclosure.

FIG. 11 is a diagram for explaining the configuration of a memory system in accordance with an embodiment of the present disclosure.

FIG. 12 is a diagram for explaining an operation method of the memory system in accordance with an embodiment of the present disclosure.

### DETAILED DESCRIPTION

Various embodiments are directed to providing a memory apparatus that can improve the durability of a memory that stores data by using the characteristic of switching between different resistance states depending on the direction of current, a memory system, and an operation method of a memory system.

The data reliability and durability of a memory can be improved.

Hereafter, some embodiments of the present disclosure are described with reference to the accompanying drawings.

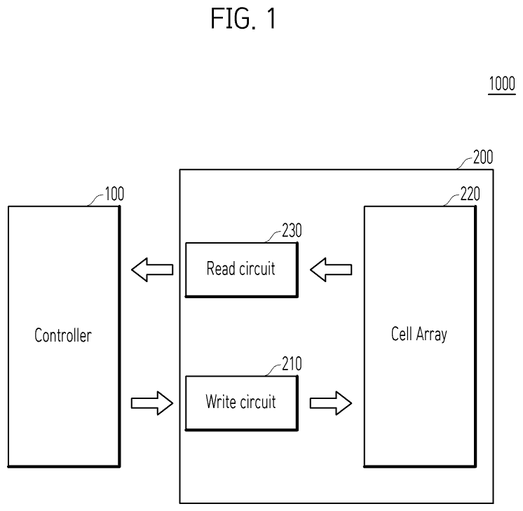

FIG. 1 is a diagram for explaining the configuration of a memory system 1000 in accordance with an embodiment of the present disclosure.

Referring to FIG. 1, the memory system 1000 may include a controller 100 and a memory apparatus 200.

In an embodiment, the controller 100 controls the memory apparatus 200 to store data therein or to output the stored data therefrom. For example, the controller 100 controls the memory apparatus 200 to perform a write operation by providing a write command, an address, and data to the memory apparatus 200. The memory apparatus 200 performs a write operation of storing data in at least one memory cell at a location corresponding to the address. In addition, the controller 100 controls the memory apparatus 200 to perform a read operation by providing a read command and an address to the memory apparatus 200. The memory apparatus 200 performs a read operation of outputting data stored in at least one memory cell at a location corresponding to the address.

In an embodiment, the controller 100 controls the memory apparatus 200 to perform a curing operation by counting an access cycle of each of a plurality of memory cells included in the memory apparatus 200. Specifically, the access cycle may refer to the number of one or more access operations performed on each of the plurality of memory cells, and these access operations include at least one read operation, at least one write operation, or both. As a result, the access cycle includes the sum of the number of write operations and the number of read operations. Accordingly, the access cycle includes the number of times the same memory cell is selected during the write operation and the read operation. For example, the controller 100 controls the memory apparatus 200 to perform a curing operation on memory cells whose access cycle exceeds a preset number of times.

In an embodiment, the memory apparatus 200 performs the read operation, the write operation, and the curing operation under the control of the controller 100.

In an embodiment, the memory apparatus 200 includes a write circuit 210, a cell array 220, and a read circuit 230.

In an embodiment, the write circuit 210 is configured to store data in the cell array 220.

In an embodiment, the read circuit 230 is configured to output stored data from the cell array 220.

In an embodiment, the cell array 220 includes a plurality of memory cells. For example, the memory cells are electrically connected between bit lines and word lines. Accordingly, the cell array 220 is configured to include a plurality of memory cells electrically connected between a plurality of bit lines and a plurality of word lines.

The memory apparatus 200 configured above can store data in at least one of the plurality of memory cells included in the cell array 220 under the control of the controller 100. In addition, the memory apparatus 200 can output stored data from at least one of the plurality of memory cells included in the cell array 220 under the control of the controller 100.

In addition, the memory apparatus 200 performs the curing operation by using the write circuit 210. In some embodiments, the write circuit 210 performs the curing operation on at least one of the plurality of memory cells on the basis of a curing command received from the controller 100. The curing operation can be applied to a memory cell whose access cycle exceeds a preset number of times among the plurality of memory cells included in the cell array 220. The curing operation includes an operation of generating heat inside a memory cell by providing a voltage to the memory cell for a period longer than a write operation period.

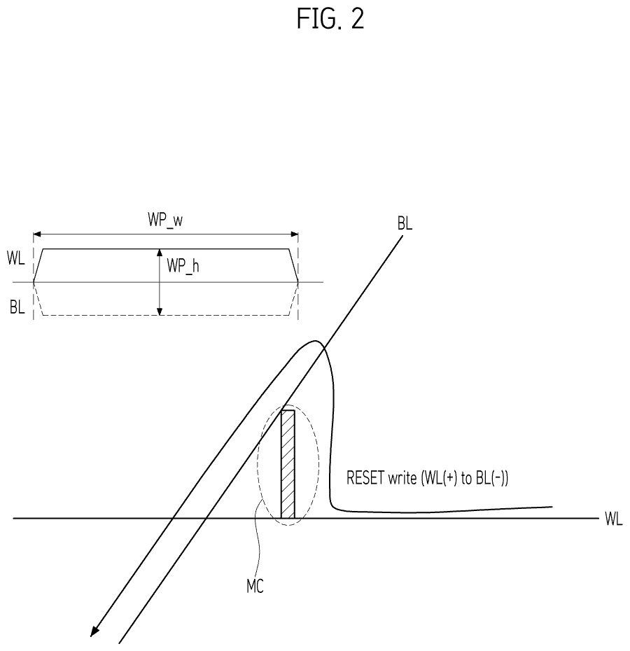

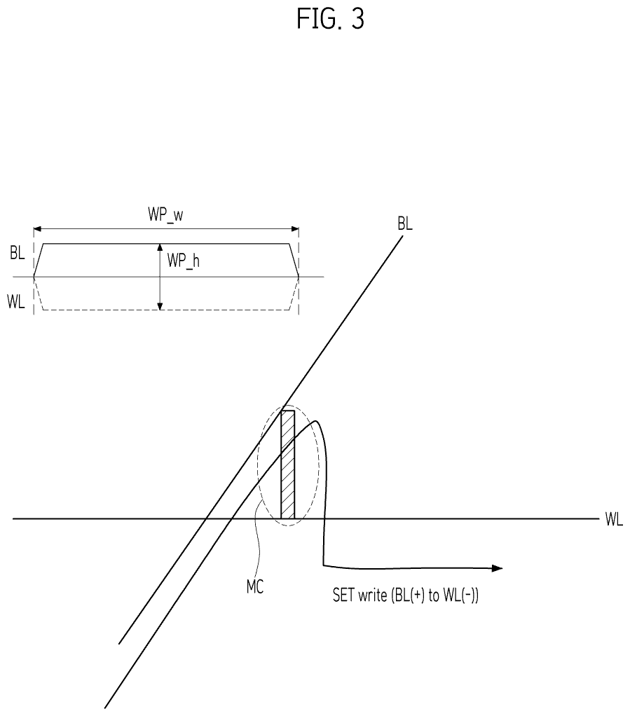

With reference to each of FIGS. 2 and 3, a write operation of the memory apparatus in accordance with an embodiment of the present disclosure is described in more detail as follows. For example, such a write operation is performed by the write circuit 210.

FIGS. 2 and 3 each are diagrams for explaining a write operation of a memory apparatus in accordance with an embodiment of the present disclosure. FIG. 2 is a drawing for explaining a reset write operation RESET write of storing reset data in a memory cell MC. A threshold voltage of the memory cell MC is changed depending on the direction of a current passing therethrough. For example, the threshold voltage of the memory cell MC is changed to one of a first level and a second level depending on the direction of the current passing therethrough. The first level is a level higher than the second level. When the level of the threshold voltage of the memory cell MC is the first level, the memory cell MC is in a reset state storing reset data. When the level of the threshold voltage of the memory cell MC is the second level, the memory cell MC is in a set state storing set data.

Referring to FIG. 2, the memory cell MC is electrically connected between a bit line BL and a word line WL. In order to store reset data in the memory cell MC and change the state of the memory cell MC to a reset state, the reset write operation RESET write in which a current flows from the word line WL to the bit line BL through the memory cell MC is performed by the write circuit 210. For example, the write circuit 210 performs the reset write operation by providing a first voltage to the word line WL, providing a second voltage to the bit line BL, and causing a current to flow from the word line WL to the bit line BL through the memory cell MC. In such a case, the first voltage is a voltage at a higher level than the second voltage. For example, the first voltage is a positive voltage + and the second voltage is a negative voltage −.

In an embodiment, during the reset write operation, the write circuit 210 generates a potential difference between both ends of the memory cell MC by providing the first voltage to the word line WL and providing the second voltage to the bit line BL for a set period of time. In such a case, the memory cell MC is turned on due to the potential difference, and the turned-on memory cell MC stores reset data by causing a current to flow from the word line WL to the bit line BL.

In an embodiment, because the write circuit 210 provides the first voltage and the second voltage to both ends of the memory cell MC, that is, the word line WL and the bit line BL, respectively, for a set period of time during the reset write operation, it can be described that the write circuit 210 provides a write pulse to the memory cell MC. The write pulse includes a width WP_w corresponding to the set period of time, and includes an amplitude WP_h corresponding to a level difference between the first voltage and the second voltage.

Referring to FIG. 3, the memory cell MC electrically connected between the bit line BL and the word line WL is subjected to a set write operation by the write circuit 210. In order to store set data in the memory cell MC and change the state of the memory cell MC to a set state, a set write operation SET write in which a current flows from the bit line BL to the word line WL through the memory cell MC is performed by the write circuit 210. For example, the write circuit 210 performs the set write operation SET write by providing the first voltage to the bit line BL, providing the second voltage to the word line WL, and causing a current to flow from the bit line BL to the word line WL through the memory cell MC. In such a case, the first voltage is a voltage at a higher level than the second voltage. For example, the first voltage is a positive voltage + and the second voltage is a negative voltage −.

In an embodiment, during the set write operation SET write, the write circuit 210 generates a potential difference between both ends of the memory cell MC by providing the first voltage to the bit line BL and providing the second voltage to the word line WL for a set period of time. In such a case, the memory cell MC is turned on due to the potential difference, and the turned-on memory cell MC stores set data by causing a current to flow from the bit line BL to the word line WL.

In an embodiment, because the write circuit 210 provides the first voltage and the second voltage to both ends of the memory cell MC, that is, the bit line BL and the word line WL, respectively, for a set period of time during the set write operation, it can be described that the write circuit 210 provides a write pulse to the memory cell MC. In such a case, the write pulse includes a width WP_w corresponding to a set period of time, and the write pulse includes an amplitude WP_h corresponding to a level difference between the first voltage and the second voltage.

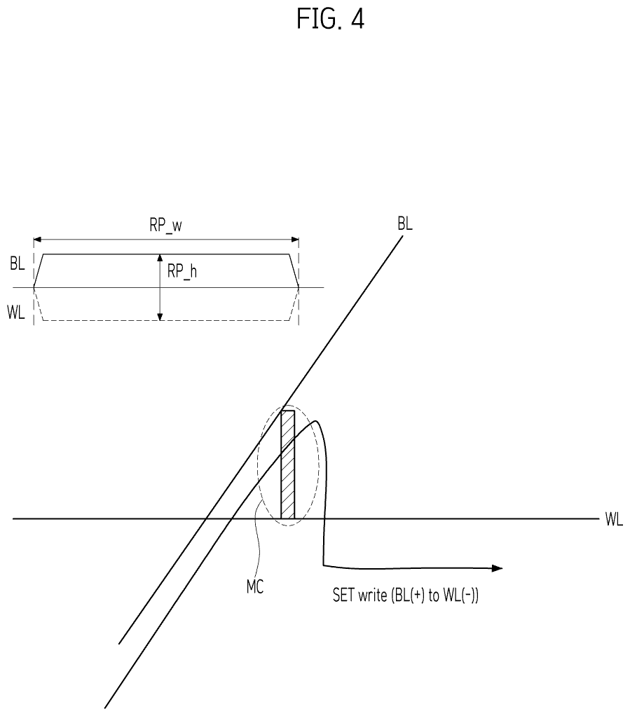

FIG. 4 is a diagram for explaining a read operation of the memory apparatus in accordance with an embodiment of the present disclosure. The read operation includes an operation for determining data stored in the memory cell MC.

Referring to FIG. 4, the memory cell MC electrically connected between the bit line BL and the word line WL is subjected to a read operation by the read circuit 230. The read circuit 230 provides the first voltage to the bit line BL and the second voltage to the word line WL. The first voltage has a level higher than the level of the second voltage. For example, the first voltage is a positive voltage + and the second voltage is a negative voltage −. In addition, the level difference between the first voltage and the second voltage is a level difference corresponding to the voltage level between a threshold voltage of a memory cell in a set state and a threshold voltage of a memory cell in a reset state.

As a result, the read circuit 230 determines whether the memory cell MC is turned on by providing the memory cell MC with a voltage with a level higher than the threshold voltage level of the memory cell MC in a set state and lower than the threshold voltage level of the memory cell MC in a reset state during the read operation. The read circuit 230 determines whether the memory cell MC is turned on by detecting a change in a current passing through the memory cell MC depending on whether the memory cell MC is turned on. For example, the read circuit 230 detects a change in a current passing through the memory cell MC through the bit line BL or the word line WL after providing the memory cell MC with a voltage with a level higher than the threshold voltage level of the memory cell MC in the set state and lower than the threshold voltage level of the memory cell MC in the reset state during the read operation. When a change in the current passing through the memory cell MC through the bit line BL or the word line WL is detected, the memory cell MC is determined to be turned on. In such a case, the memory cell MC is in a set state storing set data. However, when substantially no change in the current passing through the memory cell MC through the bit line BL or the word line WL is detected, the memory cell MC is determined to not be turned on (turned off). In such a case, the memory cell MC is in a reset state storing reset data.

In an embodiment, the read circuit 230 provides the first voltage and the second voltage to the bit line BL and the word line WL, respectively, for a set period of time so that a voltage with a level higher than the threshold voltage level of the memory cell MC in the set state and lower than the threshold voltage level of the memory cell MC in the reset state is provided to the memory cell MC during the read operation. Accordingly, because the read circuit 230 provides the first voltage and the second voltage to both ends of the memory cell MC, that is, the word line WL and the bit line BL, respectively, for a set period of time during the read operation, it can be described that the read circuit 230 provides a read pulse to the memory cell MC. In such a case, the read pulse includes a width RP_w corresponding to the set period of time, and includes an amplitude RP_h corresponding to the level difference between the first voltage and the second voltage.

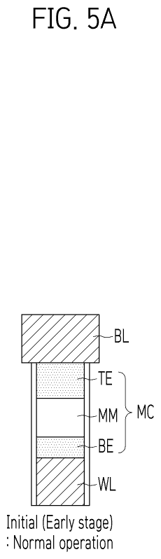

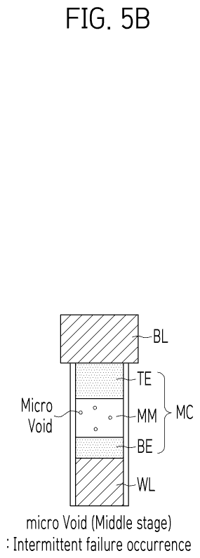

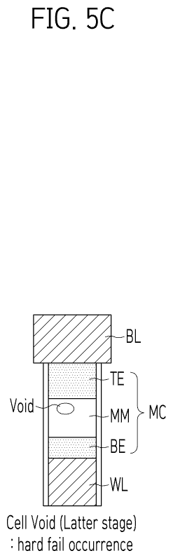

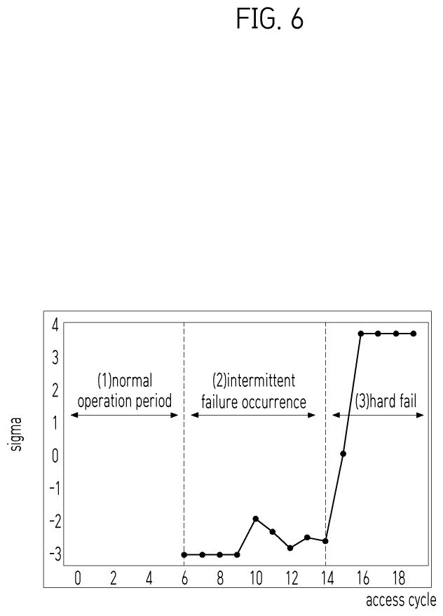

FIGS. 5A-5C and 6 are diagrams for explaining characteristics of a memory cell in accordance with an embodiment of the present disclosure.

Referring to FIGS. 5A-5C, the memory cell MC includes a first electrode (e.g., a bottom electrode) BE, a memory material MM, and a second electrode (e.g., a top electrode) TE. The first electrode BE is formed on the word line WL. The memory material MM is formed on the first electrode BE. The second electrode TE is formed on the memory material MM. The bit line BL is formed on the second electrode TE. The first and second electrodes BE each include a conductive material. The memory material MM includes a chalcogenide-based material, and the threshold voltage level of the memory material MM is changed depending on the direction of the current passing therethrough.

In an embodiment, the memory material MM receives a voltage or a current from the word line WL through the first electrode BE. In addition, the memory material MM receives a voltage or a current from the bit line BL through the second electrode TE.

In an embodiment, when a current flows in a second direction (e.g., the direction of passing through the memory material MM from the first electrode BE to the second electrode TE), that is, from the word line WL to the bit line BL, the level of the threshold voltage of the memory material MM increases. On the other hand, when a current flows in a first direction (e.g., the direction of passing through the memory material MM from the second electrode TE to the first electrode BE), that is, from the bit line BL to the word line WL, the level of the threshold voltage of the memory material MM decreases. In such a case, a case where the threshold voltage of the memory material MM increases is referred to as a reset state, and a case where the threshold voltage of the memory material MM decreases is referred to as a set state. In order to determine the level of the threshold voltage of the memory material MM, that is, to determine the state of the memory cell MC, the memory material MM receives a current in the first direction from the second electrode TE to the first electrode BE, that is, from the bit line BL to the word line WL. When a current flows through the memory material MM, it is determined as a set state, whereas when substantially no current flows through the memory material MM, it is determined as a reset state.

In this way, the operation of providing a voltage or a current to the memory material MM, that is, the memory cell MC, is referred to as an access operation, and the memory material MM gradually deteriorates as an access cycle increases.

FIG. 5A illustrates a case where the access cycle of the memory cell MC is less than a first set number of times. In such a case, the level of the threshold voltage of the memory cell MC normally changes, that is, the memory cell MC normally stores data.

FIG. 5B illustrates a case where the access cycle of the memory cell MC is equal to or greater than the first set number of times and less than a second set number of times. In such a case, a micro void is formed inside the memory material MM. Due to the generated micro void, the level of the threshold voltage of the memory cell MC intermittently changes abnormally, and thus, the memory cell MC intermittently generates an error.

FIG. 5C illustrates a case where the access cycle of the memory cell MC is greater than the second set number of times. In such a case, a void greater than a micro void is formed in the memory material MM. The level of the threshold voltage of the memory cell MC in which the void has occurred is not changed, and thus, the memory cell MC may not be able to store data. This phenomenon is referred to as a hard fail. The first and second set number of times are set number of times on the basis of the results of a test that repeatedly accesses the memory cell MC.

FIG. 6 is a graph showing an error rate for the access cycle. The error rate is a value calculated by dividing the number of error occurrences by the access cycle. For example, the error rate for the number of access operations performed on a memory cell may be obtained by dividing the number of error occurrences in the memory cell by the number of access operations performed on the memory cell.

A first period (1) in FIG. 6 corresponds to normal operation in FIG. 5A. In other words, the first period (1) is a period in which the memory cell MC operates normally. In such a case, the error rate is less than a first set value.

A second period (2) in FIG. 6 corresponds to Intermittent failure occurrence in FIG. 5B. In other words, the second period (2) is a period in which the memory cell MC intermittently generates an error. In such a case, the error rate is equal to or greater than the first set value and less than a second set value. The memory cell MC normally stores and outputs data, but intermittently stores or outputs data abnormally due to a micro void generated therein.

A third period (3) in FIG. 6 corresponds to hard fail occurrence in FIG. 5C. In other words, the third period (3) is a period in which a hard fail occurs in the memory cell MC. In such a case, the error rate exceeds the second set value.

As a result, the memory cell MC deteriorates and the error rate increases as the access cycle increases.

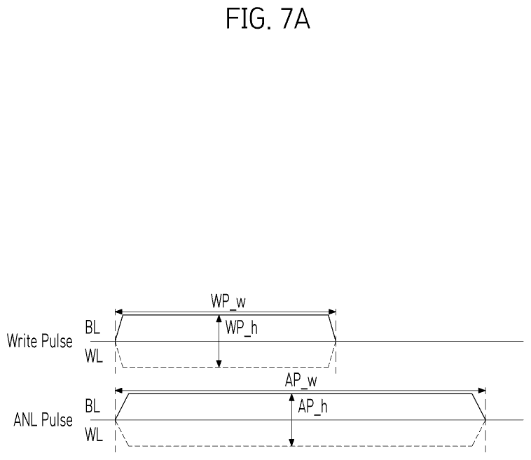

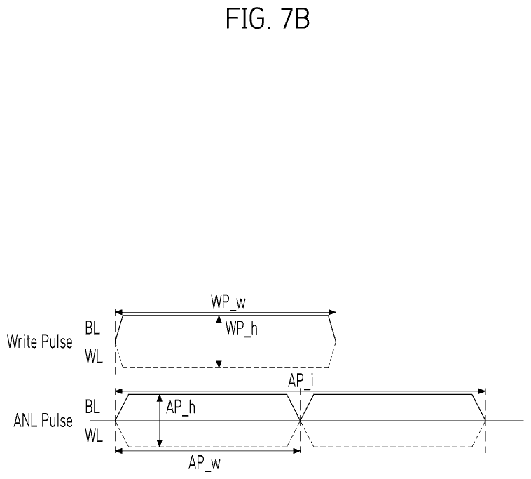

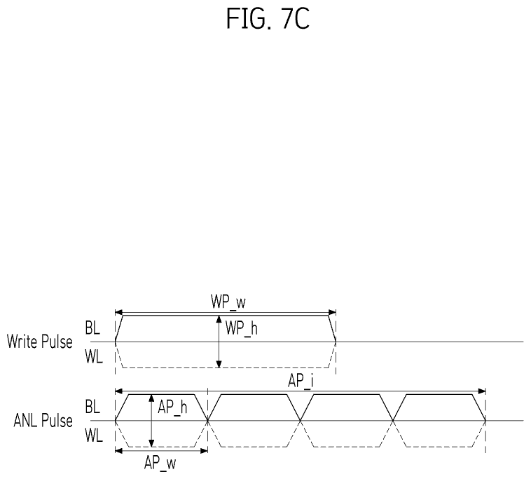

FIGS. 7A, 7B, and 7C each is a diagram for explaining a curing pulse in accordance with an embodiment of the present disclosure.

A curing operation in accordance with an embodiment of the present disclosure is an operation of providing a curing pulse ANL Pulse to the memory cell MC. The curing operation is an operation of generating heat in the memory material MM by providing a voltage equal to or higher than a threshold voltage to the memory cell MC. During the curing operation, the memory material MM is cured due to the generated heat. In such a case, when damage or micro voids exist in the interior of the memory cell MC, that is, the memory material MM, the memory cell MC is recovered through curing.

Referring to FIG. 7A, the curing pulse ANL Pulse provided to the memory cell MC during the curing operation has a width (or a curing period) AP_w longer than the width WP_w of a write pulse Write Pulse. During the curing operation, the memory cell MC receives the curing pulse ANL Pulse having a longer width AP_w than the write pulse Write Pulse. In some embodiments, the width AP_w of the curing pulse ANL is sufficiently long to ensure recovery of the memory cell MC by annealing and sufficiently short to prevent occurrence of void(s) as well as deterioration of cell uniformity. For example, the width of the curing pulse ANL Pulse may be 1 μs to 1 ms. In such a case, the memory cell MC receives at least one curing pulse ANL Pulse during the curing operation.

Referring to FIGS. 7B and 7C, during the curing operation, the memory cell MC receives a plurality of curing pulses ANL Pulse during a curing period AP_i. For example, the width AP_w of a single curing pulse ANL Pulse is shorter than the width WP_w of the write pulse Write Pulse. In addition, the curing period AP_i illustrated in FIGS. 7B and 7C corresponds to the width AP_w of the curing pulse ANL Pulse illustrated in FIG. 7A. In other words, a total sum AP_i of the widths of the plurality of curing pulses in each of FIGS. 7B and 7C may correspond to the width AP_w of the single curing pulse ANL in FIG. 7A, which is longer than the width WP_w of the write pulse Write Pulse.

In an embodiment, the amplitude AP_h of the curing pulse ANL Pulse is smaller than or equal to the amplitude WP_h of the write pulse Write Pulse. The amplitude AP_h of the curing pulse ANL Pulse is above a voltage level that can turn on the memory cell MC regardless of the state of the memory cell MC, and is smaller than or equal to the amplitude WP_h of the write pulse Write Pulse.

In an embodiment, the curing pulse ANL Pulse is a pulse provided from the write circuit 210 to the memory cell MC. That is, the write circuit 210 provides the first and second voltages to the bit line BL and the word line WL, respectively, during the curing operation, and the difference between the levels of the first and second voltages corresponds to the width AP_h of the curing pulse ANL Pulse. One or more time intervals during which the first and second voltages are provided to the bit line BL and the word line WL, respectively, correspond to the width AP_w of the curing pulse ANL Pulse as illustrated in FIG. 7A or the curing period AP_i as illustrated in FIGS. 7B and 7C.

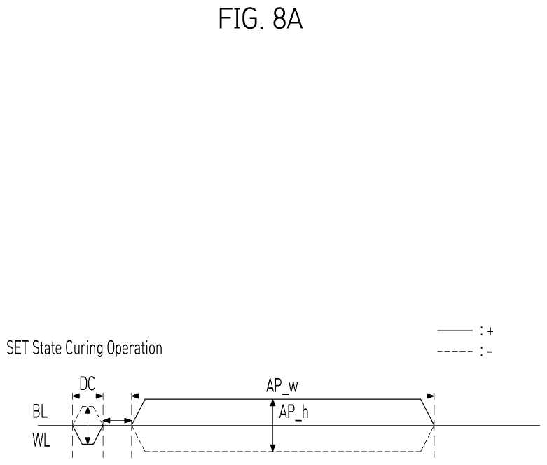

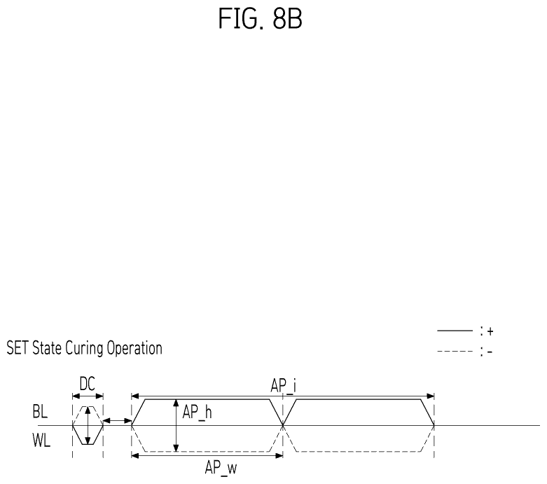

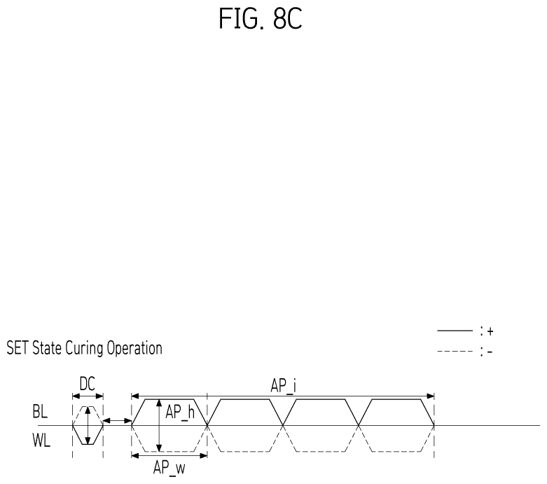

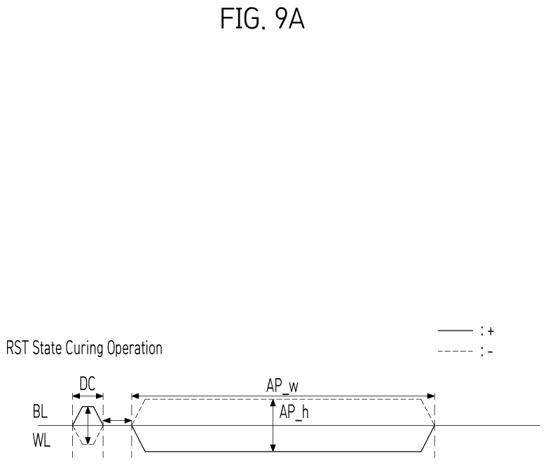

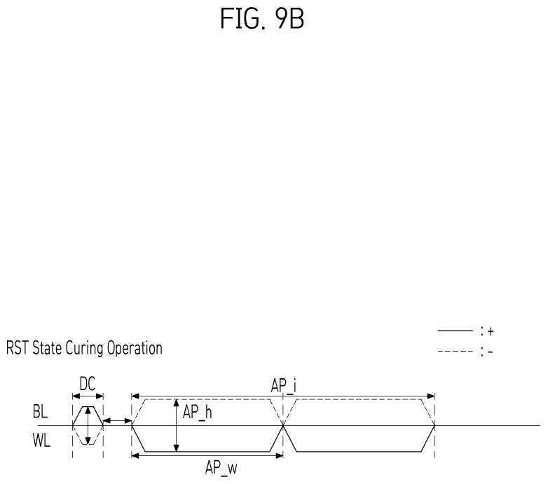

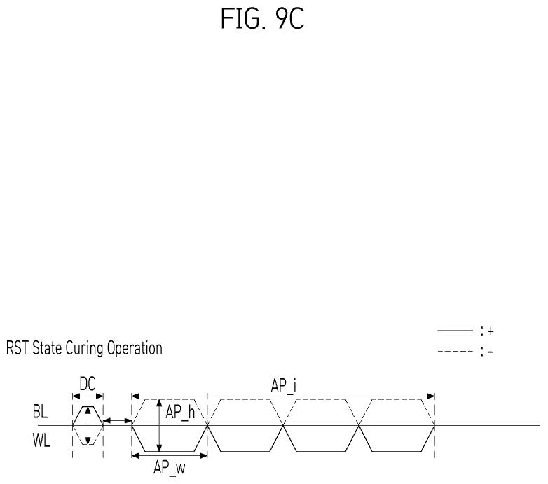

FIGS. 8A-8C and 9A-9C each are diagrams for explaining a curing operation in accordance with an embodiment of the present disclosure.

FIGS. 8A-8C each is a drawing for explaining the curing operation of the memory cell MC in a set state.

Referring to FIGS. 8A-8C, the curing operation of the memory cell MC in the set state includes providing the curing pulse ANL Pulse to the memory cell MC so that a current flows in the same direction (e.g., a first direction) as that in the SET write. For example, the curing operation of the memory cell MC in the set state is an operation of providing a first voltage + to the bit line BL and providing a second voltage − to the word line WL. In addition, the curing operation includes a drift cancellation operation period DC in which the threshold voltage of the memory cell MC in the set state is reduced by providing a current in the opposite direction (e.g., a second direction) to that in the set write SET write to the memory cell MC before providing the curing pulse ANL Pulse to the memory cell MC. In other words, when a current flows through the memory cell MC in a first direction to provide the curing pulse ANL Pulse the memory cell MC, the curing operation further includes causing a current to flow through the memory cell MC in a second direction opposite to the first direction, before providing the curing pulse to the memory cell MC. Such a drift cancellation operation may be performed to reduce a threshold voltage of the memory cell before providing the curing pulse ANL_pulse to the memory cell MC, thereby ensuring that the memory cell MC is turned on when the curing pulse ANL pulse is provided to the memory cell MC.

As illustrated in FIG. 8A, the curing operation of the memory cell MC in the set state includes an operation of providing the first voltage + to the bit line BL and providing the second voltage − to the word line WL for a longer time interval than the write operation. That is, as illustrated in FIG. 8A, the curing pulse ANP Pulse provided to the memory cell MC in the set state is a pulse formed to provide the first voltage + to the bit line BL and provide the second voltage − to the word line WL during the width AP_w of the curing pulse ANL Pulse. In such a case, the level difference between the first voltage + and the second voltage − corresponds to the amplitude AP_h of the curing pulse ANL Pulse.

As illustrated in FIGS. 8B and 8C, the curing operation of the memory cell MC in the set state includes providing a plurality of curing pulses ANL Pulse to the memory cell MC during the curing period AP_i longer than the write operation. In such a case, the memory cell MC causes a current to flow in the same direction as during the set write SET write. For example, the curing operation of the memory cell MC in the set state includes providing a curing pulse ANL Pulse with a width AP_w shorter than the width of the write pulse Write Pulse to the memory cell MC a plurality of times. As illustrated in FIGS. 8B and 8C, the curing pulse ANP Pulse provided to the memory cell MC in the set state is a pulse formed to provide the first voltage + to the bit line BL and provide the second voltage − to the word line WL during the width AP_w of the curing pulse ANL Pulse. In such a case, the level difference between the first voltage + and the second voltage − corresponds to the amplitude AP_h of the curing pulse ANL Pulse.

FIGS. 9A-9C each are a drawing for explaining the curing operation of the memory cell MC in a reset state.

Referring to FIGS. 9A-9C, the curing operation of the memory cell MC in the reset state includes providing the curing pulse ANL Pulse to the memory cell MC so that a current flows in the same direction (e.g., a second direction) as that in the reset write RESET write. For example, the curing operation of the memory cell MC in a reset state is an operation of providing the second voltage − to the bit line BL and providing the first voltage + to the word line WL. In addition, the curing operation includes a drift cancellation operation period DC in which the threshold voltage of the memory cell MC in the reset state is reduced by providing a current in the opposite direction (e.g., a first direction) to that in the reset write RESET write to the memory cell MC before providing the curing pulse ANL Pulse to the memory cell MC.

As illustrated in FIG. 9A, the curing operation of the memory cell MC in the reset state includes an operation of providing the second voltage − to the bit line BL and providing the first voltage + to the word line WL for a longer period of time (or a longer time interval) than the write operation. That is, as illustrated in FIG. 9A, the curing pulse ANP Pulse provided to the memory cell MC in the reset state is a pulse formed to provide the second voltage − to the bit line BL and provide the first voltage + to the word line WL during the width AP_w of the curing pulse ANL Pulse. In such a case, the level difference between the first voltage + and the second voltage − corresponds to the amplitude AP_h of the curing pulse ANL Pulse.

As illustrated in FIGS. 9B and 9C, the curing operation of the memory cell MC in the reset state includes providing a plurality curing pulses ANL Pulse to the memory cell MC during the curing period AP_i longer than the write operation. In such a case, the memory cell MC causes a current to flow in the same direction as during the reset write RESET write. For example, the curing operation of the memory cell MC in the reset state includes an operation of providing a curing pulse ANL Pulse having a width AP_w shorter than the width of the write pulse Write Pulse to the memory cell MC a plurality of times. As illustrated in FIGS. 9B and 9C, the curing pulse ANP Pulse provided to the memory cell MC in the reset state is a pulse formed to provide the second voltage − to the bit line BL and provide the first voltage + to the word line WL during the width AP_w of the curing pulse ANL Pulse. In such a case, the level difference between the first voltage + and the second voltage − corresponds to the amplitude AP_h of the curing pulse ANL Pulse.

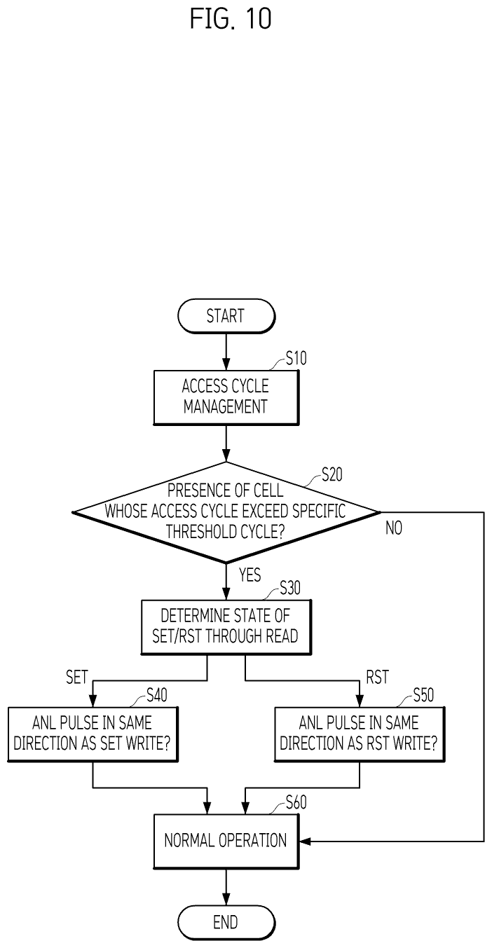

FIG. 10 is a diagram for explaining an operation method of the memory system in accordance with an embodiment of the present disclosure.

Referring to FIG. 10, the operation method of the memory system includes access management S10, an access cycle determination S20, a state determination S30, a first curing operation execution S40, a second curing operation execution S50, and a normal operation execution S60.

In an embodiment, the access management S10 includes counting an access cycle for each of the plurality of memory cells included in the memory apparatus 200. Specifically, the access management S10 may include managing (e.g., counting) the number of access operations for each of the plurality of memory cells in the memory apparatus 200. For example, the controller 100 provides an address to the memory apparatus 200 together with a read command or a write command. The controller 100 counts the number of read commands and write commands for the same address corresponding to the same memory cell. Accordingly, the access management S10 includes ascertaining whether the controller 100 has provided the read command or the write command to the memory apparatus 200 for the same address.

In an embodiment, the access cycle determination S20 includes determining the presence or absence of a memory cell whose access cycle exceeds a specific threshold number of times. Specifically, the access cycle determination S20 includes determining whether a memory cell exists among the plurality of memory cells, when the number of access operations performed on the memory cell exceeds a set number of times. For example, the access cycle determination S20 includes determining the presence or absence of a memory cell accessed beyond a specific threshold number of times, that is, a set number of times, on the basis of the counting value of the access management S10. The access cycle determination S20 may be performed by the controller 100. The specific threshold number of times (e.g., the set number of times) indicates the access cycle at which micro voids may occur in the memory material MM of the memory cell MC as illustrated in FIG. 5B. Referring to the description of FIG. 5B, the access cycle determination S20 includes determining the presence or absence of a memory cell whose access cycle falls within a range of a first set number of times or more and less than a second set number of times.

When the memory cell accessed beyond the set number of times does not exist in the access cycle determination S20 (No), the normal operation execution S60 is performed.

However, when the memory cell accessed beyond the set number of times exists in the access cycle determination S20 (Yes), the state determination S30 is performed.

In an embodiment, the state determination S30 includes determining the state of the memory cell accessed beyond the set number of times. For example, the state determination S30 includes performing a read operation on the memory cell accessed beyond the set number of times. The controller 100 determines the state of the memory cell by providing a read command to the memory apparatus 200 for the memory cell accessed beyond the set number of times.

When it is determined in the state determination S30 that the memory cell accessed beyond the set number of times is in a first state (e.g., a set state SET), the first curing operation execution S40 is performed.

On the other hand, when it is determined in the state determination S30 that the memory cell accessed beyond the set number of times is in a second state (e.g., a reset state RESET), the second curing operation execution S50 is performed.

In an embodiment, the first curing operation execution S40 includes providing the memory cell in a SET state with the curing pulse ANL Pulse that causes a current to flow in the same direction (e.g., a first direction) as during a set write operation SET write. The first curing operation execution S40 includes providing the curing pulse ANL Pulse in any of the waveforms of FIGS. 8A to 8C to the memory cell MC. The first curing operation execution S40 includes a process in which the controller 100 controls the write circuit 210 to provide voltages that generate a voltage difference corresponding to the amplitude of the curing pulse ANL Pulse for a time interval corresponding to the width of the curing pulse ANL Pulse to each of the bit line BL and the word line WL electrically connected to the memory cell. The voltage level of the bit line BL is higher than the voltage level of the word line WL.

In an embodiment, the second curing operation execution S50 includes providing the memory cell in the reset state RESET with the curing pulse ANL Pulse that causes a current to flow in the same direction (e.g., a second direction) as during the reset write operation RESET write. The second curing operation execution S50 includes providing the curing pulse ANL Pulse in any of the waveforms of FIGS. 9A to 9C to the memory cell MC. The second curing operation execution S50 includes a process in which the controller 100 controls the write circuit 210 to provide voltages that generate a voltage difference corresponding to the amplitude of the curing pulse ANL Pulse for a time interval corresponding to the width of the curing pulse ANL Pulse to each of the bit line BL and the word line WL electrically connected to the memory cell. The voltage level of the bit line BL is lower than the voltage level of the word line WL.

In an embodiment, the normal operation execution S60 includes a process in which the memory apparatus 200 performs operations such as a read operation and a write operation under the control of the controller 100.

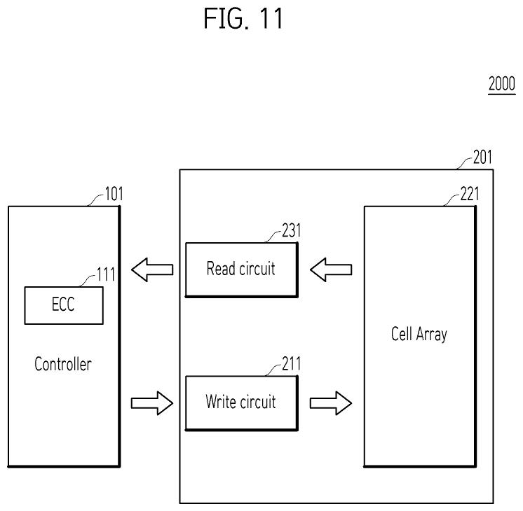

FIG. 11 is a diagram for explaining the configuration of a memory system in accordance with an embodiment of the present disclosure.

Referring to FIG. 11, a memory system 2000 includes a controller 101 and a memory apparatus 201.

In an embodiment, the controller 101 controls the memory apparatus 201 to store data therein or to output the stored data therefrom. For example, the controller 101 controls the memory apparatus 201 to perform a write operation by providing a write command, an address, and data to the memory apparatus 201. The memory apparatus 201 performs a write operation of storing data in at least one memory cell at a location corresponding to the address. In addition, the controller 101 controls the memory apparatus 201 to perform a read operation by providing a read command and an address to the memory apparatus 201. The memory apparatus 201 performs a read operation of outputting data stored in at least one memory cell at a location corresponding to the address.

In an embodiment, the controller 101 includes an error correction code (ECC) circuit 111. The ECC circuit 111 corrects and manages an error included in data output from the memory apparatus 201. The ECC circuit 111 calculates an error rate of data output from a memory cell at a location corresponding to a specific address. In addition, the controller 101 controls a memory cell to operate normally, perform a curing operation on the memory cell, and/or control the memory cell to be repaired on the basis of the error rate. For example, the controller 101 determines a memory cell whose error rate is less than a first set value, as illustrated in a normal operation period (1) of FIG. 6. That is, the controller 101 determines the memory cell whose error rate is less than the first set value through the ECC circuit 111, and controls a read operation or a write operation to be performed on the memory cell. The controller 101 determines an address at which a memory cell is located where an error occurs intermittently, as illustrated in (2) intermittent failure occurrence of FIG. 6. That is, the controller 101 determines an address where an error occurs intermittently through the ECC circuit 111. In other words, the controller 101 determines a memory cell whose error rate is equal to or greater than the first set value and less than the second set value. The controller 101 controls a curing operation to be performed on the memory cell whose error rate is equal to or greater than the first set value and less than the second set value. In addition, the controller 101 determines a memory cell in which a hard fail has occurred, as illustrated in (3) hard fail of FIG. 6. That is, the controller 101 determines a memory cell whose error rate is equal to or greater than the second set value as a memory cell where a hard fail has occurred, through the ECC circuit 111. In such a case, the controller 101 controls the memory cell whose error rate is equal to or greater than the second set value to be repaired. In some embodiments, when the controller 101 determines a memory cell whose error rate exceeds a preset value (e.g., the first set value), the controller 101 controls a curing operation to be performed on the memory cell.

In an embodiment, the memory apparatus 201 performs the read operation, the write operation, and the curing operation under the control of the controller 101.

In an embodiment, the memory apparatus 201 includes a write circuit 211, a cell array 221, and a read circuit 231.

In an embodiment, the write circuit 211 is configured to store data in the cell array 221.

In an embodiment, the read circuit 231 is configured to output stored data from the cell array 221.

In an embodiment, the cell array 221 includes a plurality of memory cells. For example, the memory cells are electrically connected between bit lines and word lines. Accordingly, the cell array 221 is configured to include a plurality of memory cells electrically connected between a plurality of bit lines and a plurality of word lines.

The memory apparatus 201 configured above can store data in at least one of the plurality of memory cells included in the cell array 221 under the control of the controller 101. In addition, the memory apparatus 201 can output stored data from at least one of the plurality of memory cells included in the cell array 221 under the control of the controller 101.

In addition, the memory apparatus 201 performs the curing operation by using the write circuit 211. The curing operation can be applied to a memory cell whose error rate is equal to or greater than the first set value and less than the second set value among a plurality of memory cells included in the cell array 221. The curing operation includes generating heat inside a memory cell by providing a voltage to the memory cell for a period longer than a write operation period. The curing operation has been described above with reference to FIGS. 5 to 9, and thus detailed descriptions thereof may be omitted in the interest of brevity.

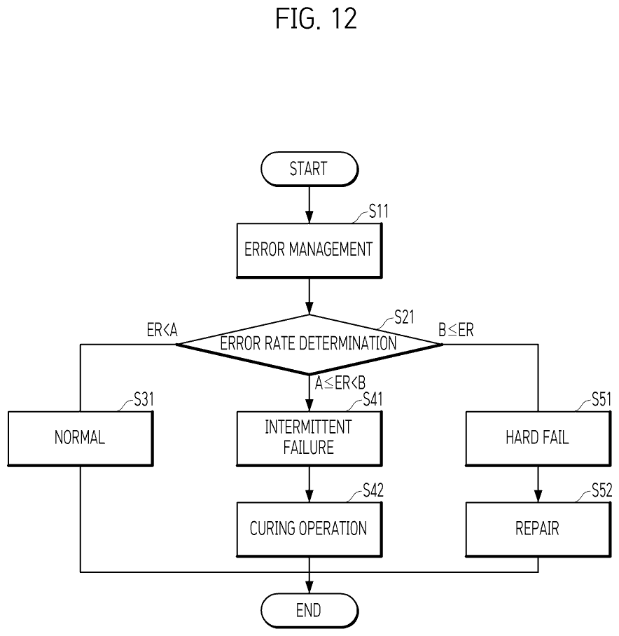

FIG. 12 is a diagram for explaining an operation method of the memory system in accordance with an embodiment of the present disclosure.

Referring to FIG. 12, the operation method of the memory system includes error management S11, an error rate determination S21, a normal determination S31, an intermittent failure determination S41, a curing operation S42, a hard fail determination S51, and a repair S52.

In an embodiment, the error management S11 includes correcting and managing an error in data output from a memory cell. For example, the error management S11 includes causing the controller 101 to perform a read operation on the memory apparatus 201 to correct and manage an error in data transmitted from the memory apparatus 201. In such a case, the controller 101 includes the ECC circuit 111 that corrects and manages an error in data transmitted from the memory apparatus 201. In addition, the ECC circuit 111 calculates an error rate for a specific address at which a corresponding memory cell is located.

In an embodiment, the error rate determination S21 includes determining the state of the memory cell on the basis of the error rate calculated in the error management S11. For example, the error rate determination S21 determines the state of the memory cell for each of the following cases: when the error rate is less than a first set value A (ER<A, ER: error rate), when the error rate is equal to or greater than the first set value A and less than a second set value B (A≤ER<B), and when the error rate is equal to or greater than the second set value B (B≤ER).

In the error rate determination S21, when the error rate is less than the first set value A (ER<A), the normal determination S31 is performed. The normal determination S31 includes determining that the memory cell whose error rate is less than the first set value A (ER<A) is in a normal state.

In the error rate determination S21, when the error rate is equal to or greater than the first set value A and less than the second set value B (A≤ER<B), the intermittent failure determination S41 is performed. The intermittent failure determination S41 includes determining a memory cell whose error rate is equal to or greater than the first set value A and less than the second set value B (A≤ER<B) to be in an intermittent failure state.

When the memory cell is determined to be in the intermittent failure state, the curing operation S42 is performed.

In an embodiment, the curing operation S42 includes generating heat inside the memory cell by providing the curing pulse ANL Pulse having a longer width than the write pulse to the memory cell. For example, the memory cell is cured due to the generated heat, so that damage or micro voids existing inside the memory cell may be recovered. For example, the amplitude of the curing pulse ANL Pulse is equal to or smaller than the amplitude of the write pulse. The minimum level of the amplitude of the curing pulse ANL Pulse is a level at which the memory cell is turned on.

In the error rate determination S21, when the error rate is equal to or greater than the second set value B (B≤ER), the hard fail determination S51 is performed. The hard fail determination S51 includes determining a memory cell whose error rate is equal to or greater than the second set value B (B≤ER) to be in a hard fail state.

When the memory cell is determined to be in the hard fail state, the repair S52 is performed. The repair S52 includes replacing a memory cell in a hard fail state with another memory cell. For example, the repair S52 includes controlling another memory cell to be selected when an address of the memory cell in the hard fail state is received.

As described above, a memory system in accordance with an embodiment of the present disclosure can recover a memory cell by setting an access cycle in which micro voids may occur and performing a curing operation on a memory cell whose access cycle exceeds a set number of times. In addition, a memory system in accordance with an embodiment of the present disclosure can recover the memory cell by performing a curing operation on a memory cell on the basis of an error rate of the memory cell.

Although some embodiments according to the technical idea of the present disclosure have been described above with reference to the accompanying drawings, various embodiments of the present disclosure are not limited to the above embodiments. Various types of substitutions, modifications, and changes may be made by those skilled in the art, to which the present disclosure pertains, and it should be construed that these substitutions, modifications, and changes belong to the scope of embodiments of the present disclosure.

What is claimed is:

1. A memory system comprising:
a memory apparatus including a plurality of memory cells; and
a controller that controls a curing operation to be performed on a first memory cell among the plurality of memory cells when the number of access operations performed on the first memory cell exceeds a preset number of times.

2. The memory system of claim 1, wherein the access operations include at least one read operation, or at least one write operation, or both.

3. The memory system of claim 1, wherein the curing operation includes generating heat inside the first memory cell.

4. The memory system of claim 3, wherein the curing operation further includes providing the first memory cell with a curing pulse with a width longer than a width of a write pulse.

5. The memory system of claim 4, wherein a current flows through the first memory cell in a first direction when the curing pulse is provided to the first memory cell, and
wherein the curing operation further includes causing a current to flow through the first memory cell in a second direction opposite to the first direction, before providing the curing pulse to the first memory cell.

6. A memory system comprising:
a memory apparatus including a plurality of memory cells; and
a controller that controls a curing operation to be performed on a first memory cell among the plurality of memory cells when an error rate of the first memory cell exceeds a preset value.

7. The memory system of claim 6, wherein the error rate includes an error rate for the number of access operations performed on the first memory cell.

8. The memory system of claim 6, wherein the curing operation includes generating heat inside the first memory cell.

9. The memory system of claim 8, wherein the curing operation includes providing the first memory cell with a curing pulse with a width longer than a width of a write pulse.

10. The memory system of claim 9, wherein an amplitude of the curing pulse is equal to or smaller than an amplitude of the write pulse.

11. The memory system of claim 9, wherein a current flows through the first memory cell in a first direction when the curing pulse is provided to the first memory cell, and
wherein the curing operation further includes causing a current to flow through the first memory cell in a second direction opposite to the first direction, before providing the curing pulse to the first memory cell.

12. The memory system of claim 6, wherein the memory apparatus further comprises a write circuit that performs the curing operation under control of the controller.

13. The memory system of claim 6, wherein the controller further comprises an error correction code (ECC) circuit that corrects and manages an error in data output from the plurality of memory cells.

14. An operation method of a memory system, comprising:
managing numbers of access operations for a plurality of memory cells;
determining whether a first memory cell exists among the plurality of memory cells, the number of access operations performed on the first memory cell exceeding a set number of times;
determining data stored in the first memory cell when the first memory cell exists; and
performing a curing operation on the first memory cell according to a result of the determining.

15. The operation method of claim 14, wherein the performing of the curing operation comprises generating heat in the first memory cell.

16. The operation method of claim 15, wherein the generating of heat in the first memory cell comprises providing a curing pulse to the first memory cell.

17. The operation method of claim 16, wherein a current flows through the first memory cell in a first direction during a set write operation, and
wherein the providing of the curing pulse to the first memory cell comprises causing a current to flow through the first memory cell in the first direction when the data stored in the first memory cell has been determined to be set data.

18. The operation method of claim 16, wherein a current flows through the first memory cell in a second direction during a reset write operation, and
wherein the providing of the curing pulse to the first memory cell comprises causing a current to flow through the first memory cell in the second direction when the data is stored in the first memory cell has been determined to be reset data.

19. The operation method of claim 16, wherein the curing pulse has a pulse width longer than a width of a write pulse and an amplitude equal to or smaller than an amplitude of the write pulse.

20. The operation method of claim 16, wherein the providing of the curing pulse to the first memory cell further comprises performing a drift cancellation operation to reduce a threshold voltage of the first memory cell before providing the curing pulse.

21. The operation method of claim 20, wherein a current flows through the first memory cell in a first direction during a set write operation, and
wherein the performing of the drift cancellation operation comprises causing a current to flow through the first memory cell in a second direction opposite to the first direction when the data is stored in the first memory cell has been determined to be set data.

22. The operation method of claim 20, wherein a current flows through the first memory cell in a second direction during a reset write operation, and
wherein the performing of the drift cancellation operation comprises causing a current to flow through the first memory cell in a first direction opposite to the second direction when the data is stored in the first memory cell to be reset data.

23. An operation method of a memory system, comprising:
correcting and managing an error in data output from a plurality of memory cells;
determining states of the plurality of memory cells each according to an error rate calculated in the managing; and
performing a curing operation based on the error rate.

24. The operation method of claim 23, wherein the determining of the states of the plurality of memory cells comprises:
determining a first memory cell having the error rate less than a first set value to be in a normal state; and
determining a second memory cell having the error rate equal to or greater than the first set value and less than a second set value to be in an intermittent failure state.

25. The operation method of a memory system of claim 24, further comprising determining a third memory cell having the error rate equal to or greater than the second set value to be in a hard fail state.

26. The operation method of claim 25, further comprising performing a repair operation on the third memory cell determined to be in the hard fail state.

27. The operation method of a memory system of claim 24, wherein the performing of the curing operation is performed on the second memory cell determined to be in the intermittent failure state.

28. The operation method of a memory system of claim 27, wherein the performing of the curing operation comprises generating heat in the second memory cell determined to be in the intermittent failure state.

29. The operation method of a memory system of claim 28, wherein the performing of the curing operation comprises providing the second memory cell with a curing pulse having a width longer than a width of a write pulse and an amplitude equal to or smaller than an amplitude of the write pulse.

30. The operation method of a memory system of claim 28, wherein the performing of the curing operation comprises providing the second memory cell with a plurality of curing pulses each having an amplitude equal to or smaller than an amplitude of a write pulse, a total sum of widths of the plurality of curing pulses being longer than a width of the write pulse.

31. A memory apparatus comprising:
a cell array including a plurality of memory cells;
a write circuit that stores data in at least first memory cell of the plurality of memory cells on the basis of a write command; and
a read circuit that outputs data from at least second memory cell of the plurality of memory cells on the basis of a read command,
wherein the write circuit cures at least third memory cell of the plurality of memory cells on the basis of a curing command.

32. The memory apparatus of claim 31, wherein the write circuit provides a write pulse to the at least first memory cell on the basis of the write command, and provides a curing pulse to the at least third memory cell on the basis of the curing command.

33. The memory apparatus of claim 32, wherein a width of the curing pulse is longer than a width of the write pulse, and an amplitude of the curing pulse is equal to or smaller than an amplitude of the write pulse.

34. The memory apparatus of claim 31, wherein the curing command is received from a controller that controls the memory apparatus when the number of access operations performed on the at least third memory cell exceeds a set number of times, or when the at least third memory cell has an error rate that exceeds a set value.
